(19) United States
(12) Patent Application Publication
(10) Pub. No.: US 2013/0073232 A1
(43) Pub. Date: Mar. 21, 2013

(54) Source Power Anomaly and Load Power Consumption Monitoring and Analysis

(71) Applicants: Richard J. Billingsley, Rossland (CA); Robert A. Dawley, Creedmoor, NC (US); Andrew Benton, Blue Bell, PA (US)

(72) Inventors: Richard J. Billingsley, Rossland (CA); Robert A. Dawley, Creedmoor, NC (US); Andrew Benton, Blue Bell, PA (US)

(73) Assignee: ELECTRONIC SYSTEMS PROTECTION, INC., Zebulon, NC (US)

(21) Appl. No.: 13/618,838

(22) Filed: Sep. 14, 2012

Related U.S. Application Data
(60) Provisional application No. 61/535,156, filed on Sep. 15, 2011.
(60) Provisional application No. 61/535,170, filed on Sep. 15, 2011.

(51) Int. Cl. G01R 21/00; G06F 19/00

(52) U.S. Cl. 702/61

(57) ABSTRACT

Power data are collected from one or more power modules that control power to a connected load. The power data may include indications of source electricity measurements and of load power consumption measurements. These measurements are correlated in space or time and a set of the correlated source electricity measurements or the correlated load power measurements is selected for presentation. The selected set of measurements is presented on a presentation device such that deviations from specified values are indicated to a user.

### RELATED APPLICATION DATA

This application claims the benefit of U.S. Provisional Patent Application 61/535,156 entitled, “System for Monitoring Power Consumption and Power Anomalies,” and of U.S. Provisional Patent Application 61/535,170 entitled, “Power Monitoring and Management with Remote Access,” both of which were filed on Sep. 15, 2011, the full disclosures of which are incorporated herein by reference.

### BACKGROUND

Power conditioners, as the term is used herein, include filter circuits to remove electrical noise from an AC supply voltage and suppressor circuits to limit transients/surges in the AC supply voltage, where such noise, transients and surges are collectively referred to herein as power anomalies. Power conditioners prevent potentially disruptive/damaging conditions from reaching connected equipment including, should the need arise, by removing power from the attached load. Power monitors, as the term is used herein, include energy usage detectors by which users can track how much power a connected load consumes. Power modules, as the term is used herein, includes either or both of power conditioning and power monitoring equipment and may include indicators of energy usage and whether the load is connected to the source (trip indicator). While these features protect connected equipment, conventional power modules do not offer insight as to what may have caused a trip condition. Accordingly, mechanisms by which supply voltage anomalies and power consumption data can be analyzed in search of causal relationships would be a valuable troubleshooting resource for technicians and other interested parties.

### SUMMARY

Power data are collected from one or more power modules that control power to a connected load. The power data may include indications of source electricity measurements and of load power consumption measurements. These measurements are correlated in space or time and a set of the correlated source electricity measurements or the correlated load power measurements is selected for presentation. The selected set of measurements is presented on a presentation device such that deviations from specified values are indicated to a user.

The above and still further features and advantages of the present inventive concept will become apparent upon consideration of the following definitions, descriptions and descriptive figures of specific embodiments thereof. While these descriptions go into specific details of certain embodiments of the inventive concept, it is to be understood that variations may and do exist and will be apparent to those skilled in the art upon review of this disclosure.

### BRIEF DESCRIPTION OF THE DRAWING

FIG. 1 is a schematic block diagram of an example power monitoring, control and analysis system by which the present general inventive concept may be embodied.

FIG. 2 is a schematic block diagram of an example power module by which the present general inventive concept may be embodied.

FIG. 3 is an illustration depicting an example log file provided by embodiments of the present general inventive concept.

FIG. 4 is a block diagram of an exemplary analyzer 400 by which the present invention may be embodied.

FIG. 5 is an exemplary analysis control set by which data for analysis can be selected and configured in embodiments of the present general inventive concept.

FIG. 6 is an exemplary analysis presentation interface by which data collected from power modules 110 can be analyzed in embodiments of the present general inventive concept may be embodied.

### DETAILED DESCRIPTION

The present inventive concept is best described through certain embodiments thereof, which are described in detail herein with reference to the accompanying drawings, wherein like reference numerals refer to like features throughout. It is to be understood that the term invention, when used herein, is intended to connote the inventive concept underlying the embodiments described below and not merely the embodiments themselves. It is to be understood further that the general inventive concept is not limited to the illustrative embodiments described below and the following descriptions should be read in such light.

Additionally, the word exemplary is used herein to mean, “serving as an example, instance or illustration.” Any embodiment of construction, process, design, technique, etc., designated herein as exemplary is not necessarily to be construed as preferred or advantageous over other such embodiments. Particular quality or fitness of the examples indicated herein as exemplary is neither intended nor should be inferred.

The figures described herein include schematic block diagrams illustrating various functional modules for purposes of description and explanation. Such diagrams are not intended to serve as electrical schematics and interconnections illustrated are merely to depict various interoperations between functional components and/or processes and are not necessarily direct electrical connections between such components. Moreover, the functionality illustrated and described via separate components need not be distributed as shown, and the discrete blocks in the diagrams are not intended to depict discrete electrical components.

It is to be noted that the terms power and electricity are used herein synonymously, although it is to be understood that such is not strictly the case. Electric power is the rate of transfer of electric energy, whereas electricity is a phenomenon resulting from the presence and flow of electric charge. The ordinarily skilled artisan will readily ascertain the proper meaning of the terms, “power,” and, “electricity,” from the context in which the terms are used.

As used herein, the term power-centric refers to power conditioning and monitoring that includes processes and data outside that of power conditioning and control per se. A power-centric system may provide control over various outlets based on signals indicative of not only voltage and current, but also of temperature and externally applied control signals, to name a few. A power-centric system may also provide the capability to monitor and control individual power outlets and to customize and/or create power settings on integrated network-addressable power conditioning and monitoring devices via remote access. Additionally, a power-centric system may provide control signals to external equipment through, for example, custom sequences established through a remote device. Data may be generated based on user-defined, predetermined conditions and thresholds, including, for example, outlet status, current draw, power consumption, and ambient temperature.

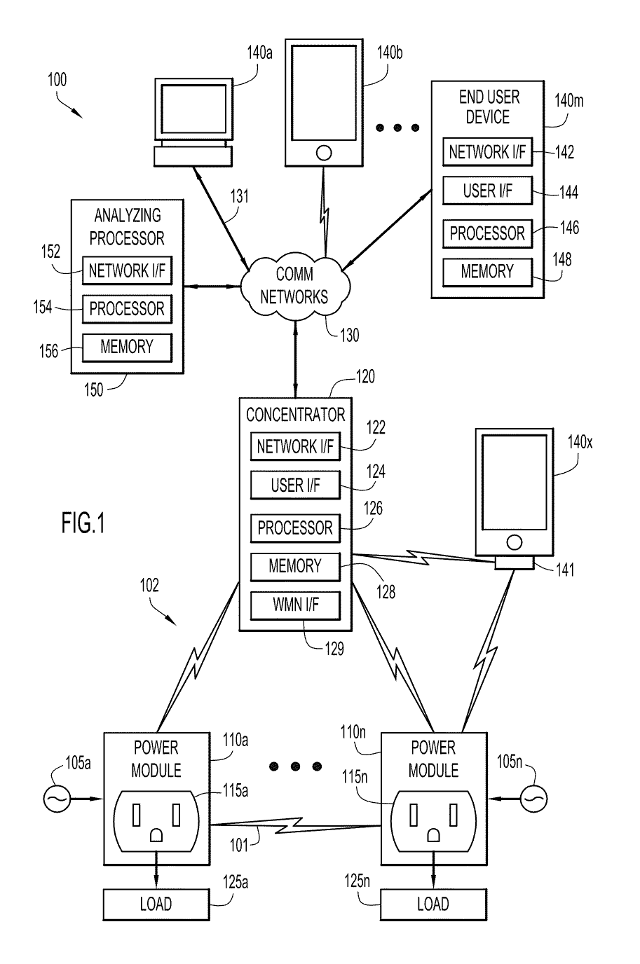

Referring to FIG. 1, there is illustrated an exemplary power-centric monitoring, control and analysis system 100 in which electrical power from power sources 105a-105n, representatively referred to as power source(s) 105, is provided to electrical loads 125a-125n, representatively referred to herein as load(s) 125, by way of power-centric power modules 110a-110n, representatively referred to herein as power module(s) 110. In addition to the provision of electrical power, power modules 110 may perform power conditioning, i.e., processing of electricity to increase its quality at respective load devices 125 and to minimize the possibility of damage to both load device 125 and the power conditioning components. Additionally, power modules 110 may perform power monitoring, i.e., periodically measuring power-centric quantities, e.g., voltage, current, environmental conditions, externally applied signals, etc., to determine whether electricity is being delivered to and consumed by load 125 in accordance with specified criteria. The measured data may be recorded and any deviation from the specified criteria, referred to herein as an event, may be suitably logged.

In certain applications, power modules 110 may be distributed over a region and may communicate with one another over one or more communication links 101. In certain embodiments of the present invention, communications links 101 may implement a wireless mesh network (WMN) 102, i.e., an ad-hoc network affording wireless communications between neighboring power modules 110. Accordingly, communications over communication links 101 may be conducted in accordance with a suitable short-range communication standard, such as ZigBee. Data may be retrieved from a power module 110 by a suitably configured end user device 140x, e.g., a mobile device having a WMN adapter 141 coupled thereto. Additionally, individual power monitors 110 may be accessed and controlled by a suitable interface implemented on end user device 140x. End user device 140x may be realized by a wide variety of wireless communication devices, such as laptop computers, tablet computers and smartphones.

In certain embodiments, power modules 110 may be communicatively coupled to a concentrator 120, which, in turn, may be communicatively coupled to a communication network 130. Although only a single concentrator 120 is illustrated in FIG. 1, system 100 may incorporate many such concentrators. Concentrator 120 may be configured to collect data from a set of power modules 110 and to provide the collected data to communication network 130. As such, concentrator 120 may include a WMN interface 129, e.g., a ZigBee interface, with which to communicate with power modules 110 and a network interface 122, e.g., an Ethernet interface, with which to communicate over communication network 130.

Concentrator 120 may include memory 128 to store processor instructions that, when executed by processor 126, implements the functionality of the concentrator 120. Such functionality may include data collection and storage, data forwarding, gateway operations, e.g., translation between WMN 102 and network 130. Memory 128 may additionally store data including information by which a particular concentrator 120 can be identified for analysis. Additionally, concentrator 120 may include a user interface 124 through which a user can configure concentrator 120, e.g., assign power modules 110 to groups, associate identifying data to power modules 110 in the group, etc.

Access to concentrator 120 may be achieved through communication network 130 by way of suitably constructed communication channels 131 between end user devices 140a-140m and 140x, representatively referred to herein as end user device(s) 140. End user devices 140 may be realized by a wide variety of wired and wireless communication devices, such as desktop computers, laptop computers, tablet computers, smartphones, and so on. Each end user device 140 may include a network interface 142 with which to communicate with concentrator 120 over communication network 130 and memory 148 to store processor instructions that, when executed by processor 146, implements the functionality of the end user device 140. Such functionality may include retrieving collected data, establishing control parameters for power modules 110, operating individual power modules, e.g., connecting and disconnecting loads 125 from sources 105, etc. Additionally, end user devices 140 may include a user interface 144 by which a user can interact with other components of system 100.

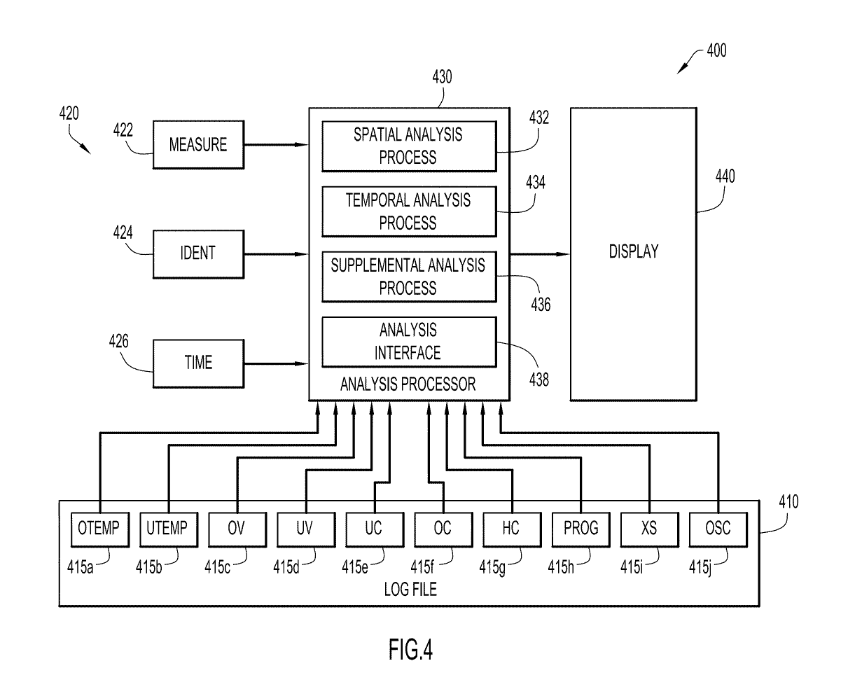

System 100 may include an analyzing processor 150 by which data collected from power modules 110 may be analyzed. Analyzing processor 150 may include a network interface 152 with which to communicate with concentrator 120 and with end user devices 140. Additionally, analyzing processor 150 may include memory 156 to store processor instructions that, when executed by processor 154, implements the functionality of the analysis processor 150. Such functionality is exemplified below with reference to FIGS. 4-6.

By way of power modules 110, power delivered from power sources 105 is conditioned and selectively output at power outlets 115a-115n, representatively referred to herein as power outlet(s) 115. The provision of power at power outlets 115 may be predicated upon whether measured phenomena, e.g., voltage, current, temperature, etc., meet certain criteria. For example, certain thresholds may be placed on the measured phenomena, e.g., input and output voltages, input and output current, power consumption, environmental conditions, externally applied control signals, etc., and, upon meeting threshold conditions, power module 110 may compel power at power outlet terminals 115 to be connected to load 125 or prevented from such connection.

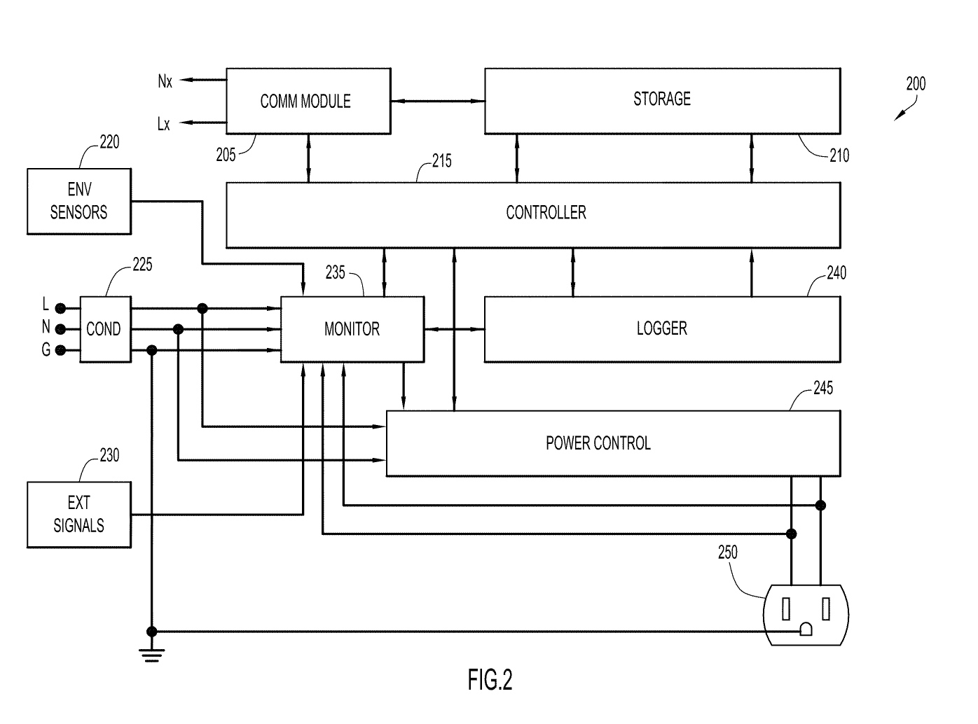

FIG. 2 is a schematic block diagram of an exemplary power module 200 suitable for operation as a power module 110 in FIG. 1. Power module 200 may be embodied to prevent power anomalies, e.g., alternating current (AC) supply surges and electrical transients, from entering connected load equipment, to monitor electrical and environmental phenomena, to collect measurement data and to control the provision of power in accordance with the measurement data.

Power module 200 may be electrically coupled to a power source 105 at input terminals L, for an AC line conductor, N, for an AC neutral conductor, and G for a ground conductor. Power module 200 may include a power outlet 250 from which an electrical load draws electrical power from power source 105 through power conditioner 225 by which source power is EMI/RFI filtered and supply voltage surges and transients are suppressed. It is to be understood that while power module 200 is illustrated as a single-phase AC power conditioning and control system, other input configurations, including multiphase AC, can be used in conjunction with the present invention without departing from the spirit and intended scope thereof.

Power outlet 250 may be independently controlled to, for example, selectively connect and disconnect the loads to and from the conditioned power based on measured power-centric quantities at each power module 200. To that end, outlet 250 may be controlled by power controller 245 that conducts electricity to outlet 250 when commanded and to disconnect outlet 250 from electricity when commanded. Commands to compel power controller 245 into conducting and non-conducting states may be provided as signals generated by monitor 235 or system controller 215, as described below.

Power controller 245 may be provided data from various sources within power monitor 200 from which control decisions can be made. For example, conditioned input power from power conditioner 225 may be provided to a monitor 235 and monitor 235 may, in turn, provide data to power controller 245 indicative of voltage and/or current levels of the input power. Power controller 245 may compare the input power levels with decision criteria, the results of such may compel appropriate action to be taken. Monitor 235 may be similarly provided signals indicative of load power characteristics, e.g., load current, energy consumption, etc., as well as signals from one or more environmental sensors 220, such as those that convert temperature, humidity, vibration and the like into electrical signals. Monitor 235 may also be provided external signals 230 the state of which may compel some action to be performed. Digital data indicative of voltage levels of such signals may be provided by monitor 235 to power controller 245, such as by analog-to-digital conversion and digital signal processing, at which power control decisions may be made.

Power controller 245 may also perform certain actions that have been programmed by a user. For example, power monitor 200 may incorporate an Application Programming Interface (API) comprising a set of commands and/or procedures that allow a user to customize the system performance, where such performance can be controlled at the outlet level. The user may utilize the API to construct a user program that establishes an action to be taken, such as a change of state in at least one of the power or auxiliary outlets, logging an event, and/or issuing alerts or alarms. A user program may include one or more program operations that compels an action in response to user-defined thresholds on measured electrical power parameters, environmental state, external signal state, or simply to define a power-up or power-down sequence at outlet 250.

Power module 200 may include a system controller, or simply controller 215, that coordinates operations between functional components thereof. For example, controller 215 may pass data and messages between components and make any cross-component format translations as necessary. Additionally, controller 215 may perform numerical computations, process interrupts, implement timers, format data for storage in storage unit 210, retrieve data from storage unit 210 on behalf of other functional components, and perform other such system control functionality. The present invention is not limited to a particular implementation of controller 215; such may be implemented by a wide array of suitable machine and/or process control methodologies without departing from the spirit and intended scope of the present invention.

Power monitor 200 may include a data logger 240 to record events, i.e., a measured quantity that exceeds established bounds that occur during operation. Such measured quantities may include measurements of input voltage level, input current level, output voltage level, output current level, power consumption, source connection polarity, temperature, humidity, external signal level, etc., and are evaluated against respective criteria at selected times. The decision criteria on the measured quantities, such as numerical bounds thereon, may be established by hard-coded mechanisms in power monitor 200 to, for example, protect sensitive system functions and/or connected equipment that would be impaired if such criteria were to be exceeded. Other bounds may be established by a user through, for example, a user program. The crossing of these bounds constitutes an event and data logger 240 tracks such events and stores information regarding these events in a log file in storage unit 210. In certain embodiments, data logger 240 logs not only events, but other data as required by the application in which the present invention is embodied.

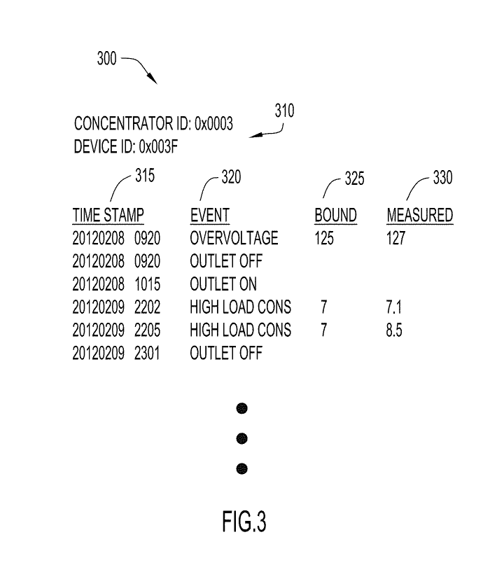

FIG. 3 illustrates an exemplary log file 300 that may be produced by data logger 240. As illustrated in the figure, log file 300 contains a header 310 that identifies the power module 110 from which the data are logged and that identifies a concentrator 120 to which the power module is associated. Log file 300 may include time/date stamp 315 indicating a time at which a corresponding event occurred, a description 320 of the event, a value 325 of a bound or threshold, where applicable, and a measured value 330 that precipitated the event. Periodically or upon command, log file 300 may be retrieved from storage 210, such as by controller 215, and provided to interested parties through a communication channel controlled by communication module 205.

Communication module 205 provides mechanisms by which access to power module 200 may be obtained by an external device. Communication module 205 may include transmitters, receivers, coders, decoders, modulators, demodulators, buffers and other such functional components to implement communications per one or more communications technologies and protocols. Such technologies and protocols may include wireless transmission and media access including radio frequency and optical transmission, wired electromagnetic media access, packet-switched and circuit-switched networks, and corresponding data format and transmission protocols, and so on. For purposes of description and not limitation, communication module 205 implements a local communication interface Lx, such as a Universal Serial Bus (USB) interface, ZigBee, etc., and a network interface Nx, such as an Ethernet interface. Through either interface Lx or Nx, one or more corresponding communication channels can be constructed and communication may be carried out in end-to-end connections constructed in the communication channels.

In normal operation, power module 200 may receive supply power through input terminals L, N and G, which may be filtered and conditioned by conditioner 225. The conditioned supply power may then be monitored through monitor 235, which converts the input power, through a measurement of voltage and/or current, into a representative signal indicative thereof. Monitor 235 may also provide representative signals indicative of, for example, load current draw and power consumption at outlets 250. The representative signals may be provided to power controller 245 and used thereby to make power control decisions against control parameters. Additionally, the representative signal from monitor 235 may be provided to data logger 240 which may store occurring events in storage unit 210 in a log file. Still further, power controller 245 may receive representative signals from environmental sensors 220 and external signals 230, which may also be used to make power control decisions.

Using the monitored parameters, multiple and diverse control schemes may be achieved by embodiments of the present invention. For example, upon the input voltage crossing a maximum safe voltage threshold level, power controller 245 may be compelled to transition into a nonconductive state, thereby removing unsafe voltage levels from attached loads. As another example, if a load attached to corresponding power outlet 250 is consuming power beyond an established threshold, power controller 245 may be compelled to transition into a nonconductive state. In each of these cases, the occurrence of the event will compel an indication of such to be provided to data logger 240, which may record the occurrence of the event, as described above.

It is to be understood that not all events need compel a power control action; certain control parameters may be set to indicate an event that need only be logged. For example, a voltage threshold may be established by a user, the crossing of which by the input voltage may be logged solely for diagnostic purposes. This voltage threshold may be set to a voltage level that is below an unsafe overvoltage level and/or above an unsafe undervoltage level where power control action would normally be compelled. Thus, during a diagnostic phase subsequent to, for example, chronic unsafe overvoltage events, logged data indicating a trend towards the unsafe voltage levels, by way of crossing the lower voltage threshold, may be useful to the technician to locate power and/or equipment problems.

The control parameters against which power controller 245 makes control decisions may be provided from an end user device 140 through a communication channel constructed through communication module 205. Controller 215 may make changes to the control parameters and/or decision criteria in accordance with the received data. For example, data may be provided by a user to modify the aforementioned unsafe overvoltage threshold from a default value, thereby creating new user-programmed decision criteria. In another example, control data may be provided by which a sequence of power related operations can be established and modified. The present invention is not limited to any set of control parameters and control data types by which such parameters are established and modified. Many alternative configurations to those illustrated and described herein can be used in conjunction with the present invention without departing from the spirit and intended scope thereof.

The present invention is not limited to any particular power module architecture. For example, power monitoring devices disclosed in Applicants' co-pending patent application Ser. No. 13/618,306 (Attorney Docket Number 0520.0052C) and in Applicants' co-pending patent application Ser. No. 13/436,103 (Attorney Docket Number 0520.0050C) may be used. The full disclosures of the afore-mentioned patent applications are incorporated herein by reference.

FIG. 4 is a block diagram of an exemplary analyzer 400 by which the present invention may be embodied. Analyzer 400 may be realized through fixed and/or programmable logic, including by way of processor instructions executing on processor 154 of analyzing processor 150. It is to be understood that while analyzer 400 is described herein as being composed of separate functional components, such is solely for purposes of explanation.

Data may be collected by analyzer 400 from power modules 110 through associated concentrators 120. Certain data may be provided in a log file 410 that contains information identifying events including, but not limited to over-temperature events 415a, which occur when the temperature around power module 110 exceeds a specified temperature, under-temperature events 415b, which occur when the temperature around power module 110 falls below a specified temperature, overvoltage events 415c, which occur when the source voltage provided to power module 110 exceeds a specified voltage, undervoltage events 415d, which occur when the source voltage provided to power module 110 falls below a specified voltage, under-current events 415e, which occur when the source current provided to power module 110 falls below a specified current level, over-current events 415f, which occur when the source current provided to power module 110 exceeds a specified current level, high power consumption events 415g, which occur when the power consumed by load 125 connected to power module 110 exceeds a specified power level, programmed events 415h, which occur when a programmed step occurs, external control signal events 415i, which occur when an externally supplied signal reaches a specified signal level, and outlet state change events 415j, which occur when an outlet changes state from the conducting state to the non-conducting state, and vice-versa. The event information items 415a-415j will be referred to herein as events 415. As described with reference to FIG. 3, log file 410 may include a timestamp for each event 415 as well as specified limits, thresholds, bounds, etc., and the measured values of parameters exceeding such limits, thresholds and bounds that precipitated the corresponding event 415.

In certain embodiments, analyzer 400 may receive non-event data 420, i.e., measurements that are made per a measurement schedule, e.g., user-specified or preset intervals at which selected parameters are sampled. Such measurements are routinely made in the normal course of operation, but may not be recorded unless specified by the user. When so specified, measurements 422, associated device identification data 424, which may include that of both power module 110 and corresponding concentrator 120, and timestamp data 426 may be collected and provided to analyzer 400 through communication network 130.

Log files 410 and non-event data 420 may be provided to analysis processor 430 by which power-centric analysis can be performed. Analysis processor 430 may be implemented by processor instructions executing on processor 154 of analyzing processor 150 illustrated in FIG. 1. Analysis processor 430 may perform various processes including, but not limited to, spatial analysis process 432, temporal analysis process 434 and supplemental analysis process 436. Among the collected data may be device identification data 424 by which each power module 110 can be identified and by which the associated concentrator 120 can be identified. Spatial analysis process 432 may have access to data, such as a lookup table, that indicates a location in space of each power module 110 based on the provided identifying information, e.g., a particular building and room in which the power module 110 is located. Such a lookup table may be configured with other data as well, such as the type of load 125 connected to the corresponding outlet 115 and the electrical circuit to which power module 110 is connected, such as might be identified by a circuit breaker in a power distribution panel. The lookup table may be configured by a user having system deployment information. The present invention is not limited to the spatially indicative information maintained by spatial analysis process 432.

Spatial analysis process 432 may perform analysis that would potentially identify causal relationships, should such exist, based on the spatial data. For example, event information 415 that corresponds to common source circuits may identify power distribution problems. Additionally, temperature events in a common room may identify environmental problems, such as cooling and heating failures. Such information may lead technicians to the cause of events that are identified by spatial commonalities.

Temporal analysis process 434 may perform analysis that would potentially identify causal relationships, should such exist, based on the temporal data. Temporal analysis process 434 may evaluate timestamps associated with event information 415 to determine whether multiple events occur within a specified span of time. For example, a high power consumption event at a power module 110 after one or more overvoltage or undervoltage events in the same power module 110 may indicate damage to one or both of the power module 110 and the connected load 125.

Supplemental analysis process 436 may perform additional analysis beyond temporal and spatial analyses. Such supplemental analysis may include joint temporal and spatial analysis that would potentially identify causal relationships, should such exist, based on both the temporal and spatial data. For example, events that are both spatially and temporally correlated, e.g., repeated and persistent outlet state changes across several power modules 115 and within a particular span of time may identify, for example, manufacturing deficiencies that may be traced to a particular manufacturing lot or batch.

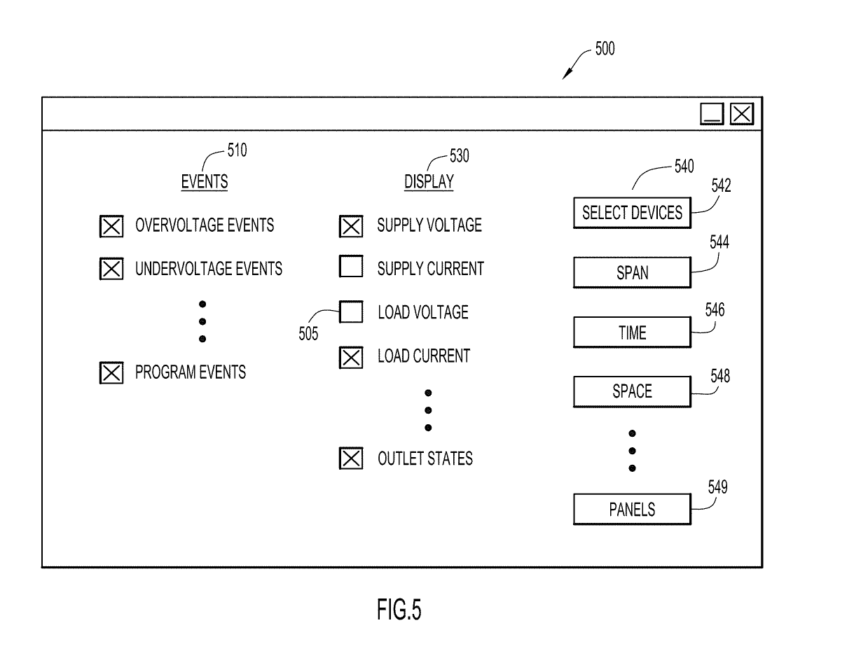

Analysis processor 430 may include an analysis interface 438 by which parameters of the analysis can be established and by which selective analysis may be presented on a display 440. FIG. 5 is an exemplary analysis control set 500 by which data for analysis can be selected and configured. Control set 500 may include controls 510 by which events may be selected, controls 520 by which analysis parameters may be selected for display, and controls 540 by which data processing may be configured. Other controls may be incorporated in embodiments of the present invention, as will be recognized and appreciated by the ordinarily skilled artisan upon review of this disclosure.

In one implementation, a user may select one or more events 510 by, for example, activation of a selection control, representatively illustrated by selection control 505. Selection of events 510 may be used as a means of sorting data by relevance. For example, a user may wish to analyze data that occurred around the time that an undervoltage and/or an overvoltage occurred. The user would then select the Overvoltage Event and Undervoltage Event controls by corresponding selection controls 505. The data that the user may wish to analyze may be selected by one or more Display controls 530. For example, the user may wish to analyze supply voltage, load current and outlet states around the time that the overvoltage and undervoltage events occurred. Accordingly, the user would select Supply Voltage, Load Current and Outlet States controls 530 by corresponding selection controls 505.

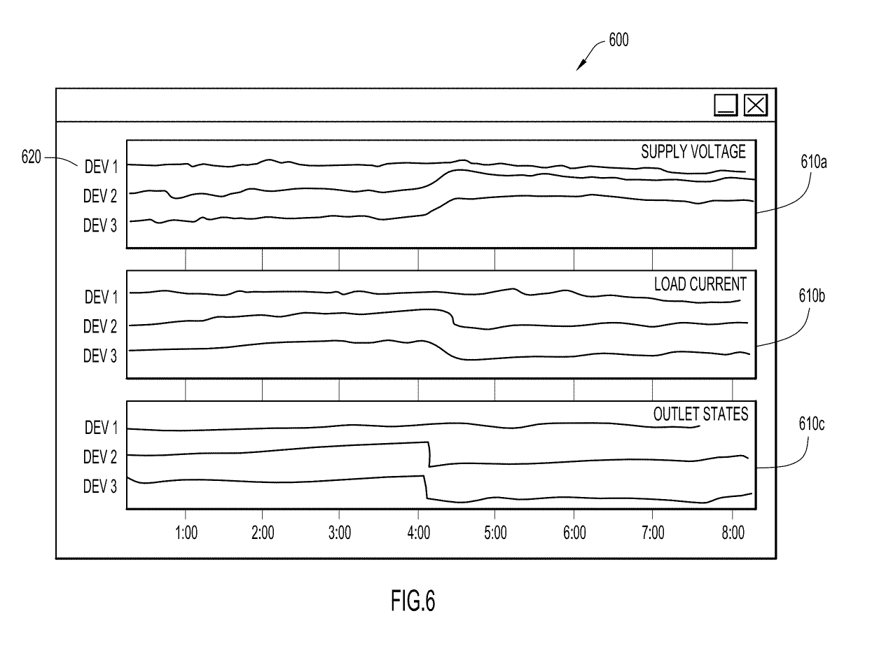

Turning momentarily to FIG. 6, an exemplary analysis presentation interface 600 is illustrated by which data collected from power modules 110 can be analyzed. Interface 600 includes one or more presentation panels 610a-610c, representatively referred to herein as presentation panel(s) 610, which may be configured in accordance with user preferences. Using the criteria selected in FIG. 5 as an example, panel 610a is configured to display supply voltage data, panel 610b is configured to display load current data and panel 610c is configured to display outlet state data. The position of each panel 610 in interface 600 may be configured in accordance with user preferences, such as through Panels control 549 in FIG. 5.

As illustrated in FIG. 5, analysis controls 540, in addition to Panels control 549, include a Select Devices control 542 by which one or more devices for analysis may be selected. Upon activating Select Devices control 542, the user may be presented with a menu (not illustrated) listing device identification information, e.g., device serial number or device identification aliases. The user may select one or more power monitors and corresponding labels may be established along presentation panes 610, as illustrated in FIG. 6. The data selected by Display control 530 for each device selected by Select Devices control 542 is then presented in each corresponding panel 610.

Analysis controls 540 may include a Span control 544 by which the user may establish a span of data to present in each presentation panel 610. For example, the data presented may span a time period from minutes to weeks, depending on the implementation. Presentation panels 610 may include navigation controls (not illustrated), such as zoom and scrolling controls, by which the user can focus on a narrower data set within the span established through Span control 544. The manner in which temporal data is displayed may be established through Time control 546 and the manner in which spatial data is displayed may be established through Space control 548.

FIG. 6 illustrates temporally correlated data and, as such, may have time indications 630 displayed thereon aligned with the data in each presentation panel 610. In the illustrated example, Device 2 and Device 3 experience an overvoltage event at substantially the same time. A technician might determine whether the two power modules are connected to the same source circuit and, if so, corrective action may be taken.

In certain embodiments, correlations that are detected and are statistically significant, i.e., determined to be more than mere coincidence, are selected for display in one or more presentation panels 610 automatically, i.e., without user selection of display parameters. When so embodied, default parameters may be enforced that establish the display parameters when such a correlation is detected.

Having described preferred embodiments of new and improved power-centric conditioning and control techniques, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

What is claimed is:

1. An apparatus comprising:
at least one power module to control power to a load connected thereto;
an analyzing processor configured to:
collect power data from the power module, the power data being indicative of source electricity measurements and of load power consumption measurements by the power module;
correlate in space or time the source electricity measurements and the load power consumption measurements; and
select a set of the correlated source electricity measurements or the correlated load power measurements; and
a presentation device to present the selected set of measurements such that deviations from specified values respectively established therefor are perceivably indicated to a human user.

2. The apparatus of claim 1, wherein:
the power module generates a log file containing data indicative of events based on the source electricity measurements and the load power consumption measurements, an event defined by the deviations from the specified values in a source electricity measurement or a load power consumption measurement meeting event criteria that compels an action associated with the event; and
the analyzing processor is further configured to:
receive the log file; and
correlate in space or time the events indicated in the log file.

3. The apparatus of claim 2, wherein the associated action is disconnecting the power from the connected load.

4. The apparatus of claim 2, wherein the log file includes source electricity measurements or power consumption measurements that compel no other action than being logged in the log file.

5. The apparatus of claim 2, wherein the log file includes at least one measurement other than the source electricity measurements and the power consumption measurements that compel an associated action.

6. The apparatus of claim 1, wherein the analyzing processor is further configured to:
determine whether a correlation exists in space or time between any of the source electricity measurements, between any of the load power consumption measurements, and between any of the source electricity measurements and any of the load power consumption measurements; and
select as the set of correlated source electricity measurement or the correlated load power measurements the correlated measurements that are determined to exist between the source electricity measurements, between the load power consumption measurements, or between the source electricity measurements and the load power consumption measurements.

7. The apparatus of claim 1, wherein the analyzing processor is further configured to:
correlate timestamps associated with each of the source electricity measurements and each of the load power measurements;
temporally align the source electricity measurements and the load power measurements in accordance with correlated timestamps.

8. The apparatus of claim 1, wherein the analyzing processor is further configured to:
correlate spatial identifiers associated with each of the source electricity measurements and each of the load power measurements;
spatially align the source electricity measurements and the load power measurements in accordance with correlated timestamps.

9. The apparatus of claim 1, wherein the analyzing processor includes an analysis interface to:
select display parameters for data presentation; and
configure the selected data in accordance with the display parameters.

10. A method comprising:
collecting power data by an analyzing processor from at least one power module that controls power to a load connected thereto, the power data being indicative of source electricity measurements and of load power consumption measurements by the power module;
correlating in space or time the source electricity measurements and the load power consumption measurements; and
selecting a set of the correlated source electricity measurements or the correlated load power measurements; and
presenting the selected set of measurements on a presentation device such that deviations from specified values respectively established therefor are perceivably indicated to a human user.

11. The method of claim 10, wherein:
generating, by the power module, a log file containing data indicative of events based on the source electricity measurements and the load power consumption measurements, an event defined by the deviations from the specified values in a source electricity measurement or a load power consumption measurement meeting event criteria that compels an action associated with the event; and
receiving the log file by the analyzing processor; and
correlate in space or time the events indicated in the log file.

12. The method of claim 11, wherein the associated action is disconnecting the power from the connected load.

13. The method of claim 11, wherein the log file includes source electricity measurements or power consumption measurements that compel no other action than being logged in the log file.

14. The method of claim 11, wherein the log file includes at least one measurement other than the source electricity measurements and the power consumption measurements that compel an associated action.

15. The method of claim 10, further comprising:
determining whether a correlation exists in space or time between any of the source electricity measurements, between any of the load power consumption measurements, and between any of the source electricity measurements and any of the load power consumption measurements; and
selecting as the set of correlated source electricity measurement or the correlated load power measurements the correlated measurements that are determined to exist between the source electricity measurements, between the load power consumption measurements, or between the source electricity measurements and the load power consumption measurements.

16. The method of claim 10 further comprising:
correlating timestamps associated with each of the source electricity measurements and each of the load power measurements;
temporally aligning the source electricity measurements and the load power measurements in accordance with correlated timestamps.

17. The method of claim 10 further comprising:
correlating spatial identifiers associated with each of the source electricity measurements and each of the load power measurements;
spatially aligning the source electricity measurements and the load power measurements in accordance with correlated spatial identifiers.

18. The method of claim 10 further comprising:
selecting display parameters for data presentation; and
configuring the selected data in accordance with the display parameters.

19. A non-transient, tangible computer-readable medium having encoded thereon processor instructions that, when executed by a processor, configures the processor to:
collect power data from at least one power module that controls power to a load connected thereto, the power data being indicative of source electricity measurements and of load power consumption measurements by the power module;
correlate in space or time the source electricity measurements and the load power consumption measurements; and
select a set of the correlated source electricity measurements or the correlated load power measurements; and
present the selected set of measurements on a presentation device such that deviations from specified values respectively established therefor are perceivably indicated to a human user.

20. The computer-readable medium of claim 19, wherein the processor instructions configure the processor to:
determine whether a correlation exists in space or time between any of the source electricity measurements, between any of the load power consumption measurements, and between any of the source electricity measurements and any of the load power consumption measurements; and
select as the set of correlated source electricity measurement or the correlated load power measurements the correlated measurements that are determined to exist between the source electricity measurements, between the load power consumption measurements, or between the source electricity measurements and the load power consumption measurements.
